(19) United States
(12) Patent Application Publication
(10) Pub. No.: US 2014/0092638 A1
(43) Pub. Date: Apr. 3, 2014

(54) COMPOUND SEMICONDUCTOR DEVICE AND METHOD OF MANUFACTURING THE SAME

(71) Applicants: FUJITSU SEMICONDUCTOR LIMITED, Yokohama-shi (JP); FUJITSU LIMITED, Kawasaki-shi (JP)

(72) Inventors: Masato Nishimori, Atsugi (JP); Yoshitaka WATANABE, Aidumisato (JP)

(73) Assignees: FUJITSU SEMICONDUCTOR LIMITED, Yokohama-shi (JP); FUJITSU LIMITED, Kawasaki-shi (JP)

(21) Appl. No.: 14/010,836

(22) Filed: Aug. 27, 2013

(30) Foreign Application Priority Data
Sep. 28, 2012 (JP) 2012-217404

(51) Int. Cl. H01L 29/778; H02M 3/335; H01L 29/66

(52) U.S. Cl. CPC H01L 29/778; H01L 29/66431; H02M 3/335
USPC 363/17; 257/194; 438/172

(57) ABSTRACT

An AlGaN/GaN.HEMT includes: a compound semiconductor layered structure; and an interlayer insulating film that covers a surface of the compound semiconductor layered structure, the interlayer insulating film including a first insulating film and a second insulating film that is formed on the first insulating film to fill irregularities on a surface of the first insulating film and has a flat surface.

### CROSS-REFERENCE TO RELATED APPLICATION

This application is based upon and claims the benefit of priority of the prior Japanese Patent Application No. 2012-217404, filed on Sep. 28, 2012, the entire contents of which are incorporated herein by reference.

### FIELD

The embodiments discussed herein are directed to a compound semiconductor device and a method of manufacturing the same.

### BACKGROUND

There is considered application of a nitride semiconductor to a semiconductor device with high withstand voltage and high output power, utilizing characteristics such as high saturation electron speed and wide band gap. For example, the band gap of GaN as the nitride semiconductor is 3.4 eV, which is larger than the band gap of Si (1.1 eV) and the band gap of GaAs (1.4 eV), and thus GaN has high breakdown electric field intensity. Accordingly, GaN is quite promising as a material of a semiconductor device for power supply which obtains high voltage operation and high output power.

As a semiconductor device using the nitride semiconductor, there have been made numerous reports on a field effect transistor, particularly a high electron mobility transistor (HEMT). For example, among GaN-based HEMTs (GaN-HEMTs), AlGaN/GaN.HEMT using GaN as an electron transit layer and AlGaN as an electron supply layer is attracting attention. In the AlGaN/GaN.HEMT, a strain resulted from a lattice constant difference between GaN and AlGaN occurs in AlGaN. Two-dimensional electron gas (2 DEG) of high concentration is obtained from piezoelectric polarization and spontaneous polarization of AlGaN caused by the strain. Accordingly, the AlGaN/GaN.HEMT is expected as a high efficiency switch element and a high-withstand-voltage electric power device for electric vehicle, or the like.

Patent Document 1: Japanese Laid-open Patent Publication No. 2012-178467

In the GaN-HEMTs, a phenomenon called current collapse that a drain current decreases at application of a high drain voltage is a problem. The current collapse is a phenomenon that when the high drain voltage is applied, electrons are trapped by the surface level or the like to interfere with flow of two-dimensional electron gas (2 DEG), resulting in decreased output current. In particular, electrons are more likely to be trapped at a location where electric fields locally concentrate between a drain electrode and a source electrode.

To address the problem, a technique is employed which suppresses the local electric field concentration by arranging a so-called field plate electrode between the drain electrode and the source electrode. The field plate electrode is an electrode electrically connected to the source electrode or the gate electrode and can change an electric field distribution to diffuse the electric field concentration location. A technique of further diffusing the electric field concentration location by forming a plurality of the field plate electrodes is also studied.

An example of a conventional AlGaN/GaN.HEMT having a plurality of field plate electrodes is illustrated in FIG. 1.

In this AlGaN/GaN.HEMT, a compound semiconductor layered structure 102 is formed on a substrate 101. The compound semiconductor layered structure 102 is composed of a buffer layer 102a, an electron transit layer 102b, an electron supply layer 102c and so on stacked in layers. Two-dimensional electron gas (2 DEG) is generated in the vicinity of an interface of the electron transit layer 102b with the electron supply layer 102c. A protective film 103 that covers the surface of the compound semiconductor layered structure 102 is formed. A gate electrode 104, a source electrode 105, and a drain electrode 106 are formed on the compound semiconductor layered structure 102, and a field plate electrode 107 is formed on the protective film 103. An interlayer insulating film 108 is formed on the protective film 103 in a manner to cover the gate electrode 104, the source electrode 105, the drain electrode 106 and the field plate electrode 107. Further, a second field plate electrode 109 which is connected to, for example, the source electrode 105 is formed on the interlayer insulating film 108.

The surface of the interlayer insulating film 108 becomes an irregular shape reflecting the shapes of the gate electrode 104, the source electrode 105, the drain electrode 106, and the first field plate electrode 107, and therefore has less surface flatness. The second field plate electrode 109 is formed on the surface of the interlayer insulating film 108, and therefore fills the irregularities on the surface and has an irregular site 111 formed on a lower surface thereof. The electric field concentration is likely to occur at the irregular site 111. There is a problem in which the occurrence of the electric field concentration causes electrons to be trapped in the interlayer insulating film 108, causing occurrence of a current collapse.

### SUMMARY

An aspect of a compound semiconductor device includes: a compound semiconductor layered structure; and an interlayer insulating film that covers a surface of the compound semiconductor layered structure, the interlayer insulating film including a first insulating film and a second insulating film that is formed on the first insulating film to fill irregularities on a surface of the first insulating film and has a flat surface.

An aspect of a method of manufacturing a compound semiconductor device includes: forming a compound semiconductor layered structure; and forming an interlayer insulating film that covers a surface of the compound semiconductor layered structure, the interlayer insulating film including a first insulating film and a second insulating film that is formed on the first insulating film to fill irregularities on a surface of the first insulating film and has a flat surface.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a schematic cross-sectional view illustrating an example of a conventional AlGaN/GaN HEMT with a plurality of field plate electrodes;

FIG. 2A to FIG. 2C are schematic cross-sectional views illustrating a method of manufacturing an AlGaN/GaN HEMT according to a first embodiment in order of processes;

FIG. 3A to FIG. 3C are schematic cross-sectional views, subsequent to FIG. 2A to FIG. 2C, illustrating the method of manufacturing the AlGaN/GaN HEMT according to the first embodiment in order of processes;

FIG. 4A and FIG. 4B are schematic cross-sectional views, subsequent to FIG. 3A to FIG. 3C, illustrating the method of manufacturing the AlGaN/GaN HEMT according to the first embodiment in order of processes;

FIG. 5A and FIG. 5B are schematic cross-sectional views, subsequent to FIG. 4A and FIG. 4B, illustrating the method of manufacturing the AlGaN/GaN HEMT according to the first embodiment in order of processes;

FIG. 6A to FIG. 6C are schematic cross-sectional views illustrating main processes in a method of manufacturing an AlGaN/GaN HEMT according to a second embodiment;

FIG. 7A to FIG. 7C are schematic cross-sectional views, subsequent to FIG. 6A to FIG. 6C, illustrating main processes in the method of manufacturing the AlGaN/GaN HEMT according to the second embodiment;

FIG. 8 is a schematic cross-sectional view illustrating the embodiment of another AlGaN/GaN HEMT;

FIG. 9 is a schematic cross-sectional view illustrating the embodiment of another AlGaN/GaN HEMT;

FIG. 10 is a connection diagram illustrating a schematic configuration of a power supply device according to a third embodiment; and

FIG. 11 is a connection diagram illustrating a schematic configuration of a high-frequency amplifier according to a fourth embodiment.

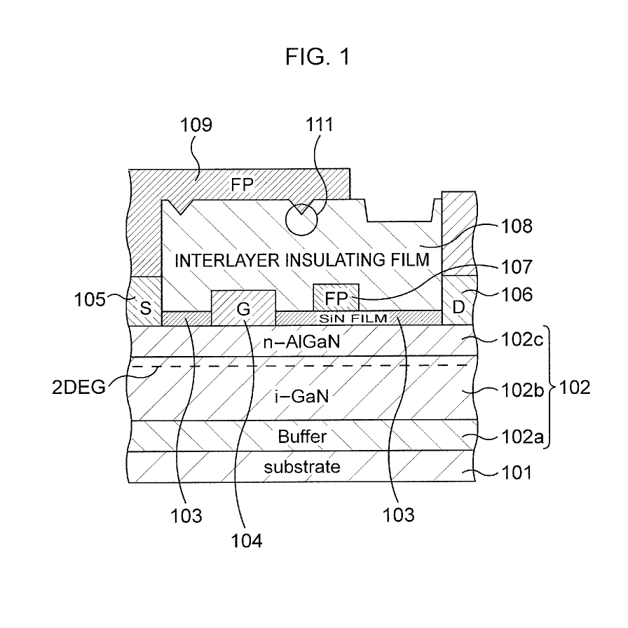

### DESCRIPTION OF EMBODIMENTS

### First Embodiment

In this embodiment, an AlGaN/GaN HEMT is disclosed as a compound semiconductor device.

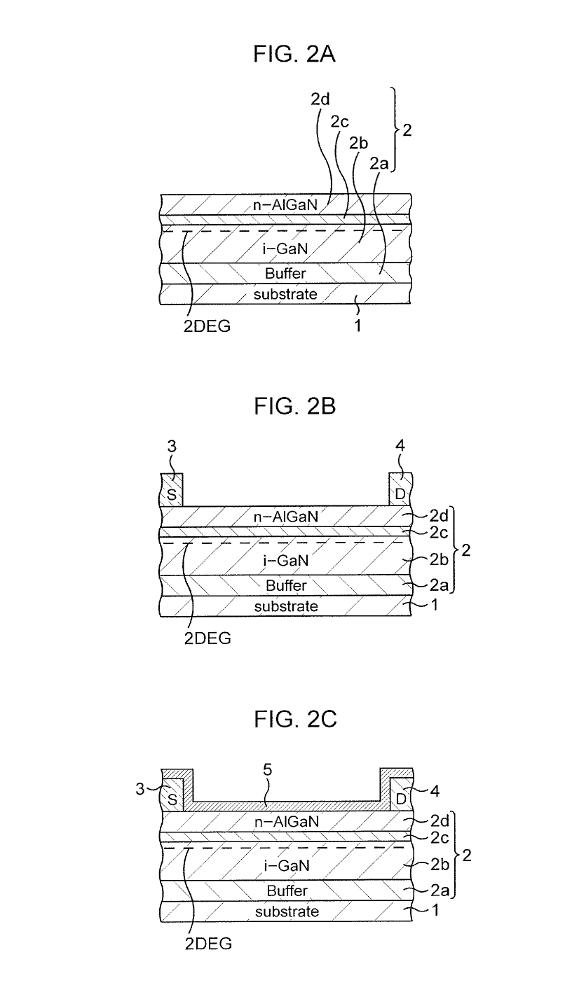

FIG. 2A to FIG. 2C to FIG. 5A and FIG. 5B are schematic cross-sectional views illustrating a method of manufacturing the AlGaN/GaN HEMT according to a first embodiment in order of processes.

First, as illustrated in FIG. 2A, a compound semiconductor layered structure 2 is formed on, for example, a semi-insulating SiC substrate 1 being a growth substrate. As the growth substrate, a Si substrate, a sapphire substrate, a GaAs substrate, a GaN substrate, or the like may be used instead of the SiC substrate. The conductivity of the substrate may be either semi-insulating or conductive.

The compound semiconductor layered structure 2 includes a buffer layer 2a, an electron transit layer 2b, an intermediate layer 2c, and an electron supply layer 2d.

In the completed AlGaN/GaN HEMI, two-dimensional electron gas (2 DEG) is generated, during operation thereof, in the vicinity of an interface, of the electron transit layer 2b, with the electron supply layer 2d (to be exact, the intermediate layer 2c). The 2 DEG is generated based on a lattice constant difference between the compound semiconductor (here, GaN) of the electron transit layer 2b and the compound semiconductor (here, AlGaN) of the electron supply layer 2d.

More specifically, on the SiC substrate 1, the following compound semiconductors are grown by, for example, an MOVPE (Metal Organic Vapor Phase Epitaxy) method. An MBE (Molecular Beam Epitaxy) method or the like may be used instead of the MOVPE method.

On the SiC substrate 1, AlN is grown to a thickness of about 200 nm, i(intentionally undoped)-GaN is grown to a thickness of about 1 μm, i-AlGaN is grown to a thickness of about 5 nm, and n-AlGaN is grown to a thickness of about 30 nm in order. Thus, the buffer layer 2a, the electron transit layer 2b, the intermediate layer 2c, and the electron supply layer 2d are formed. As the buffer layer 2a, AlGaN may be used instead of AlN, or GaN may be grown at a low temperature. On the electron supply layer 2d, n-GaN is grown to form a thin cap layer in some cases.

As a growth condition of AlN, mixed gas of trimethylaluminum (TMAl) gas and ammonia (NH₃) gas is used as a source gas. As a growth condition of GaN, mixed gas of trimethylgallium (TMGa) gas and NH₃ gas is used as a source gas. As a growth condition of AlGaN, mixed gas of TMAl gas, TMGa gas, and NH₃ gas is used as a source gas. According to the compound semiconductor layers to be grown, whether or not to supply the TAMl gas being an Al source and the TMGa gas being a Ga source and flow rates thereof are appropriately set. The flow rate of the NH₃ gas being a common source is set to about 100 ccm to about 10 LM. Further, growth pressure is set to about 50 Torr to about 300 Torr, and growth temperature is set to about 1000° C. to about 1200° C.

In order to grow AlGaN as an n-type, that is, to grow n-AlGaN of the electron supply layer 2d, for example, SiH₄ gas containing Si as n-type impurity, for example, is added to the source gas at a predetermined flow rate, thereby doping AlGaN with Si. A doping concentration of Si is set to about 1×10¹⁸/cm³ to about 1×10²⁰/cm³, for example, set to about 5×10¹⁸/cm³.

Subsequently, element isolation structures are formed.

More specifically, argon (Ar), for instance, is injected to the element isolation structures in the compound semiconductor layered structure 2. Thus, the element isolation structures are formed in regions deeper from the surface of the compound semiconductor layered structure 2 than the 2 DEG in the electron transit layer 2c. The element isolation structures demarcate an active region on the compound semiconductor layered structure 2.

Incidentally, the element isolation may be performed using, instead of the above injection method, for example, an STI (Shallow Trench Isolation) method or the like. In this event, for example, chlorine-based etching is used for dry etching of the compound semiconductor layered structure 2.

Subsequently, as illustrated in FIG. 2B, a source electrode 3 and a drain electrode 4 are formed.

More specifically, a resist is applied on the compound semiconductor layered structure 2, and processed by lithography to form openings which expose formation planned regions for the source electrode and the gate electrode (electrode formation planned regions) on the surface of the compound semiconductor layered structure 2. Thus, a resist mask having the openings is formed.

Using this resist mask, Ti/Al (a lower layer is Ti and an upper layer is Al) for example is deposited as an electrode material by the vapor deposition method for example, on the resist mask including the inside of the openings for exposing the electrode formation planned regions. The thickness of Ti is about 20 nm, and the thickness of Al is about 200 nm. By the lift-off method, the resist mask and Ti/Al deposited thereon are removed. Thereafter, the SiC substrate 1 is heat treated at a temperature of about 400° C. to about 1000° C., for example, about 550° C., in a nitrogen atmosphere for example, thereby bringing the remaining Ti/Al into ohmic contact with the electron supply layer 2d. As long as the ohmic contact of Ti/Al with the electron supply layer 2d can be obtained, there may be cases where the heat treatment is unnecessary. Thus, the source electrode 3 and the drain electrode 4 are formed.

Subsequently, as illustrated in FIG. 2C, a protective film 5 is formed.

More specifically, silicon nitride (SiN) is deposited on the compound semiconductor layered structure 2 to a thickness of, for example, about 30 nm to about 500 nm, for example, 100 nm by a plasma CVD method, a sputtering method or the like. Thus, the protective film 5 is formed.

By using SiN for a passivation film that covers the compound semiconductor layered structure 2, the current collapse can be reduced.

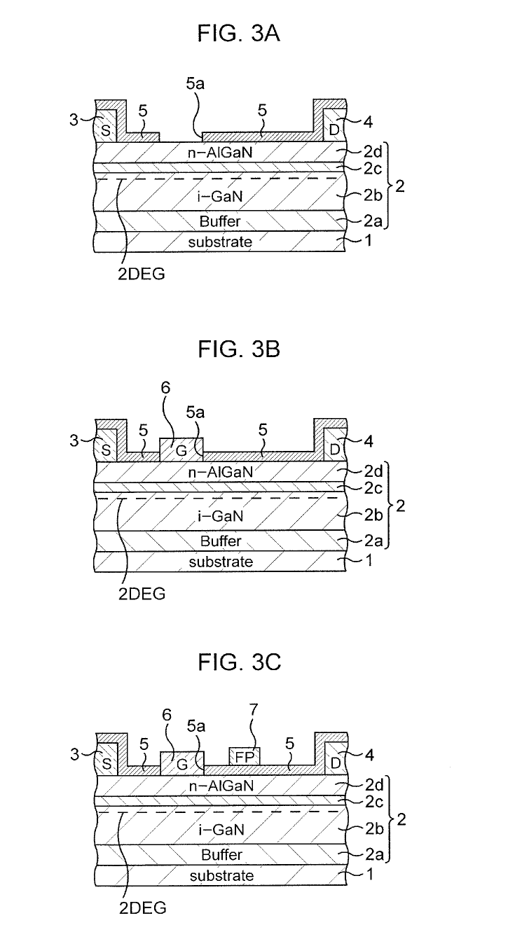

Subsequently, as illustrated in FIG. 3A, an electrode recess 5a is formed in the protective film 5.

More specifically, first, a resist is applied on the surface of the protective film 5. The resist is processed by lithography to form an opening in the resist which exposes the surface of the protective film 5 corresponding to a formation planned region for the gate electrode (electrode formation planned region). Thus, a resist mask having the opening is formed.

Using this resist mask, the electrode formation planned region of the protective film 5 is dry etched and removed until the surface of the electron supply layer 2d is exposed. Thus, the electrode recess 5a which exposes the electrode formation planned region on the electron supply layer 2d is formed in the protective film 5. For the dry etching, for example, fluorine-based etching gas is used. The dry etching is required to cause etching damage to the electron supply layer 2d as little as possible, and the dry etching using the fluorine-based gas causes little etching damage to the electron supply layer 2d.

The electrode recess may be formed by wet etching using a fluorine-based solution instead of the dry etching.

Thereafter, the resist mask is removed by ashing using oxygen plasma or wetting using a chemical solution.

Subsequently, as illustrated in FIG. 3B, a gate electrode 6 is formed.

More specifically, first, a resist is applied on the whole surface including the surface of the protective film 5. The resist is processed by lithography to form an opening in the resist which exposes the electrode recess 5a. Thus, a resist mask having the opening is formed.

Ni/Au (a lower layer is Ni and an upper layer is Au) for example is deposited as an electrode material by the vapor deposition method for example, on the resist mask including the opening which exposes the electrode recess 5a. The thickness of Ni is about 30 nm, and the thickness of Au is about 400 nm. By the lift-off method, the resist mask and Ni/Au deposited thereon are removed. Thus, the gate electrode 6 is formed such that the inside of the electrode recess 5a is filled with part of the electrode material. The gate electrode 6 is in Schottky contact with the surface of the electron supply layer 2d.

Subsequently, as illustrated in FIG. 3C, a first field plate electrode 7 is formed.

More specifically, first, a resist is applied on the whole surface including the surface of the protective film 5. The resist is processed by lithography to form an opening in the resist which exposes a formation planned region for the first field plate electrode (electrode formation planned region) between the drain electrode 4 and the gate electrode 6. Thus, a resist mask having the opening is formed.

Using this resist mask, Al for example is deposited as an electrode material by the vapor deposition method for example, on the resist mask including the opening for exposing the electrode formation planned region. The thickness of Al is about 200 nm. By the lift-off method, the resist mask and Al deposited thereon are removed. Thus, the first field plate electrode 7 is formed on the protective film 5 between the drain electrode 4 and the gate electrode 6.

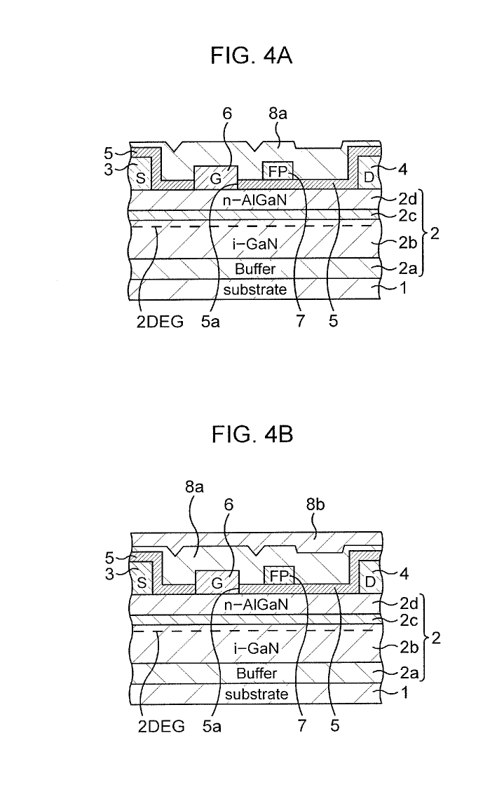

Subsequently, as illustrated in FIG. 4A, a first insulating film 8a is formed.

More specifically, an insulator, for example, silicon oxide (SiO₂) is deposited on the protective film 5 to a thickness of, for example, about 300 nm in a manner to cover the source electrode 3, the drain electrode 4, the gate electrode 6 and the first field plate electrode 7. Thus, the first insulating film 8a is formed. SiO₂ is deposited by the CVD method using, for example, tetraethoxysilane (TEOS) as a material. SiO₂ may be deposited by the CVD method using silane or triethoxysilane as a material instead of using TEOS. Further, it is also conceivable to deposit SiN, SiON or the like instead of SiO₂. The surface of the formed first insulating film 8a becomes an irregular shape reflecting the shapes of the source electrode 3, the drain electrode 4, the gate electrode 6 and the first field plate electrode 7. Note that the irregular state on the surface of the first insulating film 8a illustrated in FIG. 4A is one example, and the surface of the first insulating film 8a becomes various irregular states reflecting the shapes of the source electrode 3, the drain electrode 4, the gate electrode 6, the first field plate electrode 7, and not-illustrated structures and so on.

Subsequently, as illustrated in FIG. 4B, a second insulating film 8b is formed.

More specifically, for example, an organic SOG (Spin ON Glass) film with a film density lower than that of the first insulating film 8a is applied by rotation in a manner to cover the top of the first insulating film 8a, and heat treated in a nitrogen atmosphere. Thus, the second insulating film 8b is formed which fills irregularities on the surface of the first insulating film 8a and has a flat surface. The second insulating film 8b is formed to a thickness of, for example, about 200 nm.

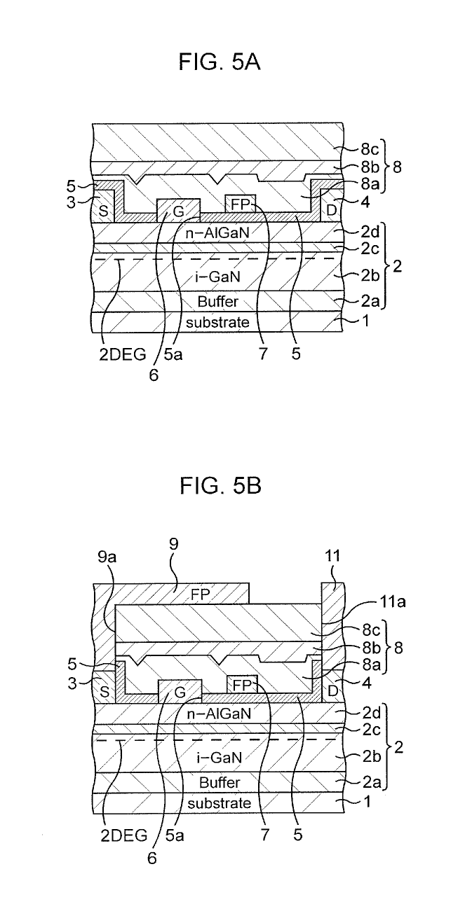

Subsequently, as illustrated in FIG. 5A, a third insulating film 8c is formed.

On the second insulating film 8b, for example, SiO₂ is deposited to a thickness of, for example, about 300 nm. Thus, the third insulating film 8c is formed. Since the surface of the second insulating film 8b is flat, the surface of the third insulating film 8c formed thereon becomes also flat. SiO₂ is deposited by the CVD method using TEOS as a material as with the first insulating film 8a. The first insulating film 8a, the second insulating film 8b, and the third insulating film 8c constitute an interlayer insulating film 8 with a flat surface.

Subsequently, as illustrated in FIG. 5B, a second field plate electrode 9 and a wiring layer 11 are formed.

More specifically, first, contact holes 9a, 11a are formed in the interlayer insulating film 8 and the protective film 5.

A resist is applied on the surface of the interlayer insulating film 8. The resist is processed by lithography to form openings in the resist which expose the surface of the interlayer insulating film 8 corresponding to connection planned regions to the source electrode and the drain electrode (electrode connection planned regions). Thus, a resist mask having the openings is formed.

The electrode connection planned regions of the interlayer insulating film 8 and the protective film 5 are dry etched and removed until the surfaces of the source electrode 3 and the drain electrode 4 are exposed. As an etching gas, for example, fluorine-based gas is used. Thus, the contact holes 9a, 11a are formed in which the surfaces of the source electrode 3 and the drain electrode 4 are exposed at their bottom surfaces.

Thereafter, the resist mask is removed by ashing using oxygen plasma or wetting using a chemical solution.

Subsequently, a resist is applied on the interlayer insulating film 8. The resist is processed by lithography to form openings in the resist which expose formation planned regions for the second plate filed electrode and the wiring layer containing the contact holes 9a, 11a Thus, a resist mask having the openings is formed.

Using this resist mask, for example, Al is deposited as an electrode and wiring material by the vapor deposition method for example, on the resist mask including the inside of the openings for exposing the formation planned regions. The thickness of Al is about 200 nm. By the lift-off method, the resist mask and Al deposited thereon are removed. Thus, the second field plate electrode 9 which fills the contact hole 9a and is electrically connected to the source electrode 3 is formed on the interlayer insulating film 8. At the same time, the wiring layer 11 which fills the contact hole 11a and is electrically connected to the drain electrode 4 is formed on the interlayer insulating film 8. The second filed plate electrode may be connected to the gate electrode 6 instead of the source electrode 3.

Thereafter, through predetermined post-processes, the Schottky-type AlGaN/GaN.HEMT according to this embodiment is formed.

In this embodiment, the second field plate electrode 9 and the wiring layer 11 are formed on the interlayer insulating film 8 having a flat surface. Therefore, a lower surface of the second field plate electrode 9 and a lower surface of the wiring layer 11 become flat surfaces without irregularities which cause electric field concentration. With this structure, occurrence of local electric field concentration caused by the interlayer insulating film is suppressed.

As described above, according to this embodiment, a highly reliable AlGaN/GaN HEMT is realized which suppresses occurrence of the current collapse due to the interlayer insulating film to improve the device characteristics.

Further, since the occurrence of the local electric field concentration in the interlayer insulating film is suppressed, the transistor withstand voltage is improved, so that a higher-withstand-voltage AlGaN/GaN HEMT is obtained.

### Second Embodiment

This embodiment discloses a structure and a method of manufacturing a Schottky-type AlGaN/GaN HEMT as in the first embodiment but is different from the first embodiment in that the interlayer insulating film is formed in more layers. Note that the same constituent members and so on as those in the first embodiment will be denoted by the same reference signs, and a detailed description thereof will be omitted.

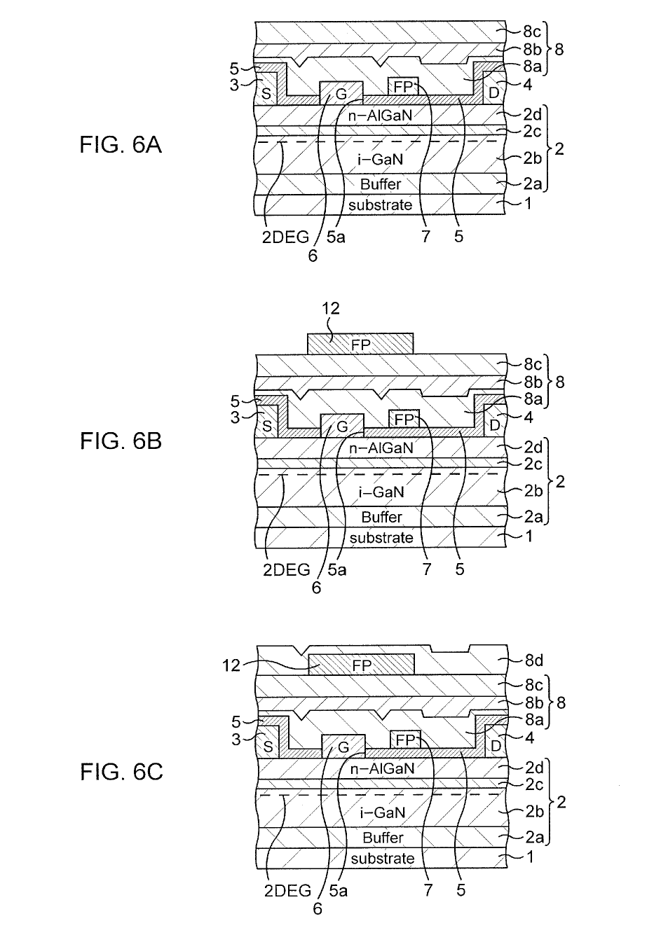

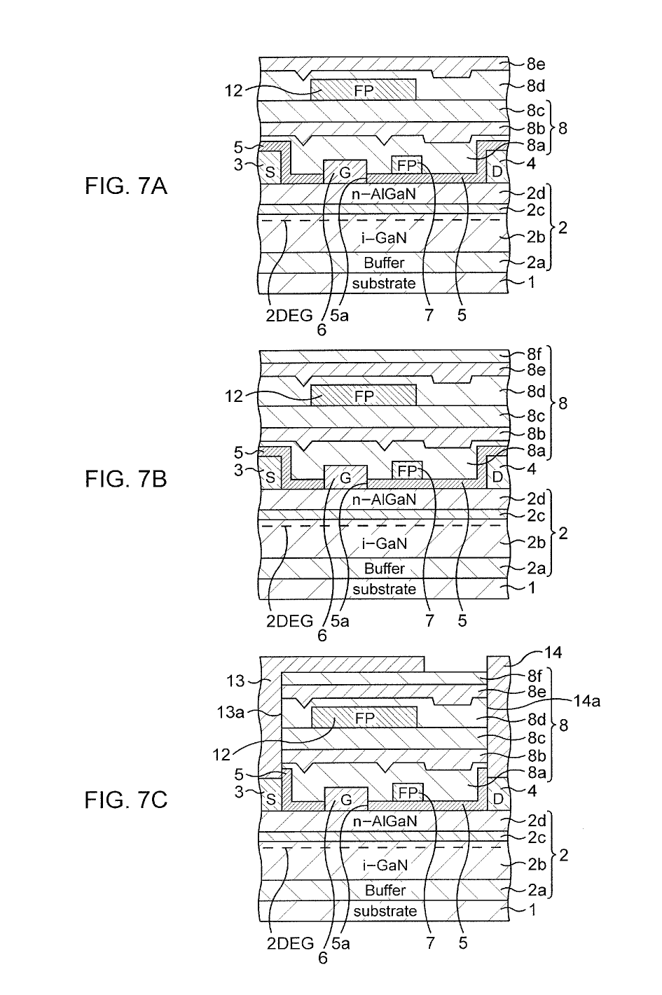

FIG. 6A to FIG. 6C and FIG. 7A to FIG. 7C are schematic cross-sectional views illustrating main processes in the method of manufacturing the AlGaN/GaN HEMT according to a second embodiment.

First, the same processes as those in FIG. 2A to FIG. 5A of the first embodiment are performed. The appearance at that time is illustrated in FIG. 6A. In FIG. 6A, a first insulating film 8a, a second insulating film 8b, and a third insulating film 8c are formed in layers as a part of the interlayer insulating film.

Subsequently, as illustrated in FIG. 6B, a second field plate electrode 12 is formed.

More specifically, first, a resist is applied on the third insulating film 8c. The resist is processed by lithography to form an opening in the resist which exposes a formation planned region for the second field plate electrode (electrode formation planned region). Thus, a resist mask having the opening is formed.

Using this resist mask, for example, Al is deposited as an electrode material by the vapor deposition method for example, on the resist mask including the inside of the opening for exposing the formation planned region. The thickness of Al is about 200 nm. By the lift-off method, the resist mask and Al deposited thereon are removed. Thus, the second field plate electrode 12 is formed on the third insulating film 8c. The second field plate electrode 12 is electrically connected to a source electrode 3 or a gate electrode 6.

Subsequently, as illustrated in FIG. 6C, a fourth insulating film 8d is formed.

More specifically, an insulator, for example, silicon oxide (SiO₂) is deposited on the third insulating film 8c to a thickness of, for example, about 300 nm in a manner to cover the second field plate electrode 12. Thus, the fourth insulating film 8d is formed. SiO₂ is deposited by the CVD method using, for example, TEOS as a material. The surface of the formed fourth insulating film 8d becomes an irregular shape reflecting the shape of the second field plate electrode 12. Note that the irregular state on the surface of the fourth insulating film 8d illustrated in FIG. 6C is one example, and the surface of the fourth insulating film 8d becomes various irregular states reflecting the shapes of the second field plate electrode 12 and not-illustrated structures and so on.

Subsequently, as illustrated in FIG. 7A, a fifth insulating film 8e is formed.

More specifically, for example, an organic SOG film with a film density lower than that of the fourth insulating film 8d is applied by rotation in a manner to cover the top of the fourth insulating film 8d, and heat treated in a nitrogen atmosphere. Thus, the fifth insulating film 8e is formed which fills irregularities on the surface of the fourth insulating film 8d and has a flat surface. The fifth insulating film 8e is formed to a thickness of, for example, about 200 nm.

Subsequently, as illustrated in FIG. 7B, a sixth insulating film 8f is formed.

On the fifth insulating film 8e, for example, SiO₂ is deposited to a thickness of, for example, about 300 nm. Thus, the sixth insulating film 8f is formed. Since the surface of the fifth insulating film 8e is flat, the surface of the sixth insulating film 8f formed thereon becomes also flat. SiO₂ is deposited by the CVD method using TEOS as a material as with the fourth insulating film 8d. The first insulating film 8a, the second insulating film 8b, the third insulating film 8c, the fourth insulating film 8d, the fifth insulating film 8e, and the sixth insulating film 8f constitute the interlayer insulating film 8 with a flat surface.

Subsequently, as illustrated in FIG. 7C, wiring layers 13, 14 are formed.

More specifically, first, contact holes 13a, 14a are formed in the interlayer insulating film 8 and the protective film 5.

A resist is applied on the surface of the interlayer insulating film 8. The resist is processed by lithography to form openings in the resist which expose the surface of the interlayer insulating film 8 corresponding to connection planned regions to the source electrode and the drain electrode (electrode connection planned regions). Thus, a resist mask having the openings is formed.

The electrode connection planned regions of the interlayer insulating film 8 and the protective film 5 are dry etched and removed until the surfaces of the source electrode 3 and the drain electrode 4 are exposed. As an etching gas, for example, fluorine-based gas is used. Thus, the contact holes 13a, 14a are formed in which the surfaces of the source electrode 3 and the drain electrode 4 are exposed at their bottom surfaces.

Thereafter, the resist mask is removed by ashing using oxygen plasma or wetting using a chemical solution.

Subsequently, a resist is applied on the interlayer insulating film 8. The resist is processed by lithography to form openings in the resist which expose formation planned regions for the wiring layers containing the contact holes 13a, 14a. Thus, a resist mask having the openings is formed.

Using this resist mask, for example, Al is deposited as an electrode and wiring material by the vapor deposition method for example, on the resist mask including the inside of the openings for exposing the formation planned regions. The thickness of Al is about 3000 nm. By the lift-off method, the resist mask and Al deposited thereon are removed. Thus, the wiring layer 13 which fills the contact hole 13a and is electrically connected to the source electrode 3 is formed on the interlayer insulating film 8. At the same time, the wiring layer 14 which fills the contact hole 14a and is electrically connected to the drain electrode 4 is formed on the interlayer insulating film 8.

Thereafter, through predetermined post-processes, the Schottky-type AlGaN/GaN.HEMT according to this embodiment is formed.

In this embodiment, the second field plate electrode 9 and the wiring layer 11 are formed on the third insulating film 8c having a flat surface. Similarly, the wiring layers 13, 14 are formed on the interlayer insulating film 8 having a flat surface. Therefore, a lower surface of the second field plate electrode 9 and a lower surface of the wiring layer 11 become flat surfaces without irregularities which cause electric field concentration. Similarly, lower surfaces of the wiring layers 13, 14 become flat surfaces without irregularities which cause electric field concentration. With this structure, occurrence of local electric field concentration caused by the interlayer insulating film is suppressed.

As described above, according to this embodiment, a highly reliable AlGaN/GaN HEMT is realized which suppresses occurrence of the current collapse due to the interlayer insulating film to improve the device characteristics.

Further, since the occurrence of the local electric field concentration in the interlayer insulating film is suppressed, the transistor withstand voltage is improved, so that a higher-withstand-voltage AlGaN/GaN HEMT is obtained.

In the above first embodiment, in order to form an interlayer insulating film having a flat surface, the irregularities on the surface of the first insulating film 8a are filled to form the second insulating film 8b having a flat surface, whereby the interlayer insulating film 8 having a flat surface is finally formed. Further, in the second embodiment, the irregularities on the surface of the fourth insulating film 8d are filled to form the fifth insulating film 8e having a flat surface, whereby the interlayer insulating film 8 having a flat surface is finally formed.

The surface of the interlayer insulating film can be made flat, for example, even by a surface polishing method, for example, a CMP (Chemical Mechanical Polishing) method, instead of employing the above method.

In this case, for example, after the process in FIG. 3C in the first embodiment, for example, SiO₂ is deposited on the protective film 5 in a manner to cover the source electrode 3, the drain electrode 4, the gate electrode 6, and the first field plate electrode 7. SiO₂ is deposited by the CVD method using, for example, TEOS as a material. The surface of the deposited SiO₂ becomes an irregular shape reflecting the shapes of the source electrode 3, the drain electrode 4, the gate electrode 6, and the first field plate electrode 7.

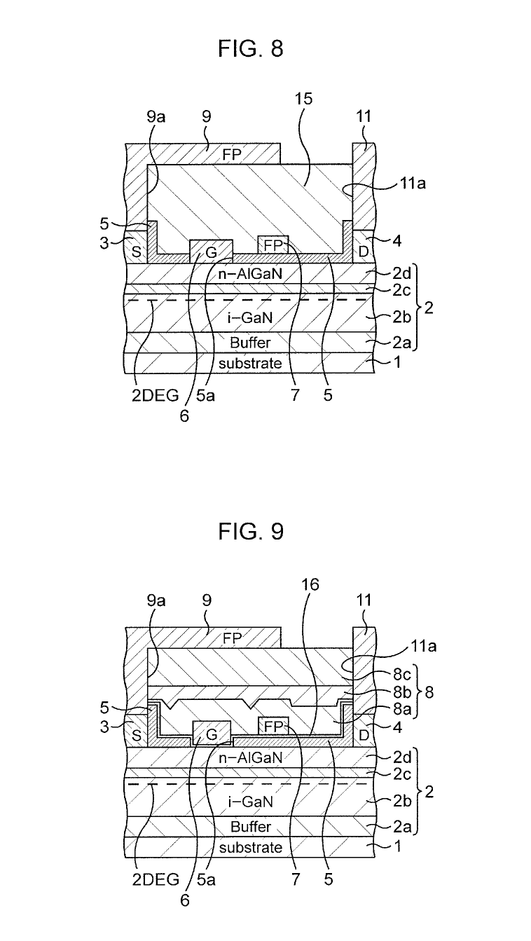

The surface of the SiO₂ is polished by the CMP method. Thus, the surface of the SiO₂ is made flat. Thereafter, through the same processes as those in FIG. 4A to FIG. 5B, an AlGaN/GaN.HEMT is formed. The structure corresponding to FIG. 5B is exemplified in FIG. 8.

Also in this case, the second field plate electrode 9 and the wiring layer 11 are formed on an interlayer insulating film 15 having a flat surface. Therefore, a lower surface of the second field plate electrode 9 and a lower surface of the wiring layer 11 become flat surfaces without irregularities which cause electric field concentration. With this structure, occurrence of local electric field concentration caused by the interlayer insulating film is suppressed.

Further, the Schottky-type AlGaN/GaN HEMTs in which the gate electrode 6 is in Schottky contact with the surface of the compound semiconductor layered structure 2 are exemplified in the above first and second embodiments. The AlGaN/GaN HEMT is not limited to this structure but can be made a MIS-type AlGaN/GaN HEMT in which the gate electrode is arranged on the compound semiconductor layered structure via a gate insulating film.

In this case, for example, after the process in FIG. 3A in the first embodiment, for example, Al₂O₃ is deposited as an insulating material on the protective film S in a manner to cover the inner wall surface of the electrode recess 5a. Al₂O₃ is deposited to a thickness of about 2 nm to about 200 nm, here, about 50 nm, for example, by an ALD (Atomic Layer Deposition) method. Thus, the gate insulating film is formed.

Incidentally, for the deposition of Al₂O₃, a plasma CVD method, a sputtering method, or the like, for instance, may be used instead of the ALD method. Further, instead of depositing Al₂O₃, a nitride or an oxynitride of Al may be used. Besides, an oxide, a nitride, an oxynitride of Si, Hf, Zr, Ti, Ta, or W or a multilayer of appropriately selected ones from among these may be deposited to form the gate insulating film.

Thereafter, through the same processes as those in FIG. 3B to FIG. 5B, an AlGaN/GaN.HEMT is formed. The structure corresponding to FIG. 5B is exemplified in FIG. 9. A numeral 16 denotes a gate insulating film.

Also in this case, the second field plate electrode 9 and the wiring layer 11 are formed on the interlayer insulating film 8 with a flat surface. Therefore, the lower surface of the second field plate electrode 9 and the lower surface of the wiring layer 11 become flat surfaces without irregularities which cause electric field concentration. With this structure, occurrence of local electric field concentration caused by the interlayer insulating film is suppressed.

### Third Embodiment

This embodiment discloses a power supply device including the AlGaN/GaN HEMT according to the first or second embodiment.

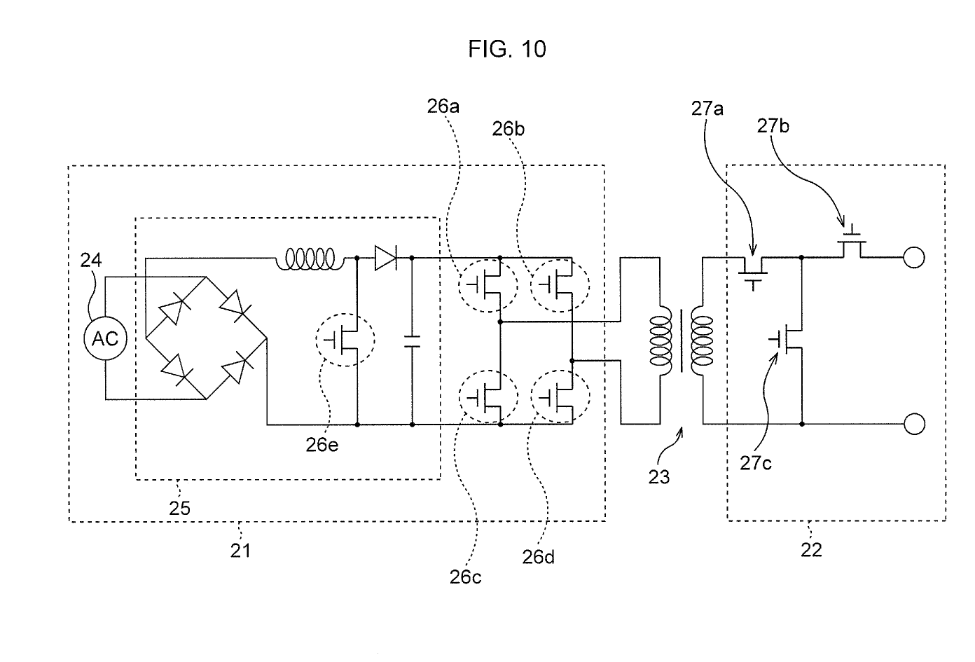

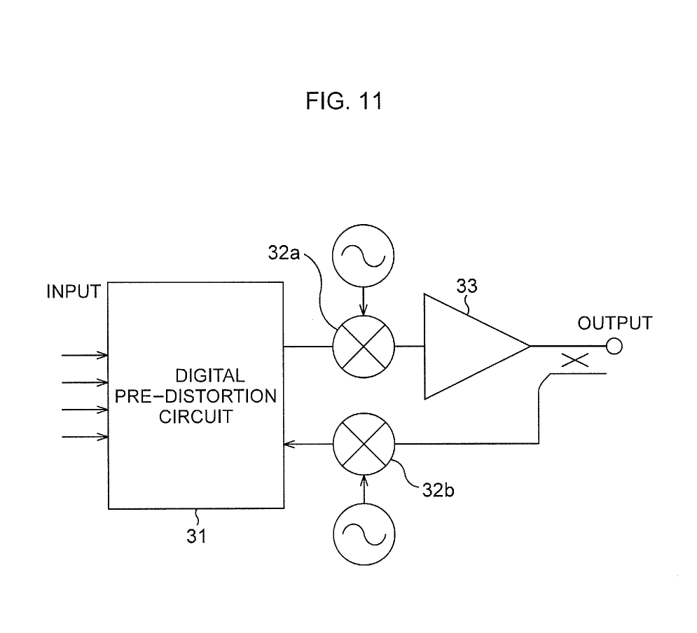

FIG. 10 is a connection diagram illustrating a schematic configuration of a power supply device according to a third embodiment.

The power supply device according to this embodiment includes a high-voltage primary-side circuit 21, a low-voltage secondary-side circuit 22, and a transformer 23 disposed between the primary-side circuit 21 and the secondary-side circuit 22.

The primary-side circuit 21 includes an AC power supply 24, a so-called bridge rectifying circuit 25, and a plurality of (four here) switching elements 26a, 26b, 26c, 26d. Further, the bridge rectifying circuit 25 has a switching element 26e.

The secondary-side circuit 22 includes a plurality of (three here) switching elements 27a, 27b, 27c.

In this embodiment, the switching elements 26a, 26b, 26c, 26d, 26e of the primary-side circuit 21 are each the AlGaN/GaN HEMT according to the first or second embodiment. On the other hand, the switching elements 27a, 27b, 27c of the secondary-side circuit 22 are each an ordinary MIS.FET using silicon.

In this embodiment, a highly reliable high-withstand-voltage AlGaN/GaN HEMT which suppresses occurrence of the current collapse due to the interlayer insulating film to improve the device characteristics is applied to a power supply circuit. This realizes a highly reliable large-power power supply circuit.

### Fourth Embodiment

This embodiment discloses a high-frequency amplifier including the AlGaN/GaN HEMT according to the first or second embodiment.

FIG. 11 is a connection diagram illustrating a schematic configuration of a high-frequency amplifier according to a fourth embodiment.

The high-frequency amplifier according to this embodiment includes a digital pre-distortion circuit 31, mixers 32a, 32b, and a power amplifier 33.

The digital pre-distortion circuit 31 compensates nonlinear distortion of an input signal. The mixer 32a mixes the input signal whose nonlinear distortion is compensated and an AC signal. The power amplifier 33 amplifies the input signal mixed with the AC signal, and has the AlGaN/GaN HEMT according to the first or second embodiment. In FIG. 11, by, for example, changing the switches, an output-side signal can be mixed with the AC signal by the mixer 32b, and the resultant can be sent out to the digital pre-distortion circuit 31.

In this embodiment a highly reliable high-withstand-voltage AlGaN/GaN HEMT which suppresses occurrence of the current collapse due to the interlayer insulating film to improve the device characteristics is applied to a high-frequency amplifier. This realizes a highly reliable high-withstand-voltage high-frequency amplifier.

### Other Embodiments

In the first to fourth embodiments, the AlGaN/GaN HEMTs are exemplified as the compound semiconductor devices. Other than the AlGaN/GaN HEMTs, the following HEMTs are applicable as the compound semiconductor devices.

### Other HEMT

### EXAMPLE 1

This example discloses an InAlN/GaN HEMT as a compound semiconductor device.

InAlN and GaN are compound semiconductors whose lattice constants can be made close to each other by their compositions. In this case, in the above-described first to fourth embodiments, the electron transit layer is formed of i-GaN, the intermediate layer is formed of i-InAlN, and the electron supply layer is formed of n-InAlN. In this case, piezoelectric polarization barely occurs, and thus the two-dimensional electron gas mainly occurs by spontaneous polarization of InAlN.

According to this example, a highly reliable high-withstand-voltage InAlN/GaN HEMT is realized which suppresses occurrence of the current collapse due to the interlayer insulating film to improve the device characteristics, as in the above-described AlGaN/GaN HEMTs.

### Other HEMT

### EXAMPLE 2

This example discloses an InAlGaN/GaN HEMT as a compound semiconductor device.

GaN and InAlGaN are compound semiconductors that the lattice constant of the latter can be made smaller than the lattice constant of the former by their compositions. In this case, in the above-described first to fourth embodiments, the electron transit layer is formed of i-GaN, the intermediate layer is formed of i-InAlGaN, and the electron supply layer is formed of n-InAlGaN.

According to this example, a highly reliable high-withstand-voltage InAlGaN/GaN HEMT is realized which suppresses occurrence of the current collapse due to the interlayer insulating film to improve the device characteristics, as in the above-described AlGaN/GaN HEMTs.

According to above aspects, a highly reliable high-withstand-voltage compound semiconductor device is realized which suppresses occurrence of current collapse due to an interlayer insulating film to improve device characteristics.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A compound semiconductor device, comprising:
a compound semiconductor layered structure; and
an interlayer insulating film that covers a surface of the compound semiconductor layered structure,
the interlayer insulating film comprising:
a first insulating film; and
a second insulating film that is formed on the first insulating film to fill irregularities on a surface of the first insulating film and has a flat surface.

2. The compound semiconductor device according to claim 1, further comprising:
a gate electrode and a first field plate electrode above the compound semiconductor layered structure,
wherein the first insulating film has the irregularities formed on the surface thereof by the gate electrode and the first field plate electrode.

3. The compound semiconductor device according to claim 1,
wherein the interlayer insulating film further comprises a third insulating film that is formed on the second insulating film and has a flat surface.

4. The compound semiconductor device according to claim 3, further comprising:
a second field plate electrode formed on the third insulating film.

5. The compound semiconductor device according to claim 3,
wherein the interlayer insulating film further comprises:
a fourth insulating film formed on the third insulating film; and
a fifth insulating film that is formed on the fourth insulating film to fill irregularities on a surface of the fourth insulating film and has a flat surface.

6. The compound semiconductor device according to claim 5,
wherein the interlayer insulating film further comprises a sixth insulating film that is formed on the fifth insulating film and has a flat surface.

7. The compound semiconductor device according to claim 6, further comprising:
a wiring layer formed on the sixth insulating film.

8. A method of manufacturing a compound semiconductor device, comprising:
forming a compound semiconductor layered structure; and
forming an interlayer insulating film that covers a surface of the compound semiconductor layered structure,
the interlayer insulating film comprising:
a first insulating film; and
a second insulating film that is formed on the first insulating film to fill irregularities on a surface of the first insulating film and has a flat surface.

9. The method of manufacturing a compound semiconductor device according to claim 8, further comprising:
forming a gate electrode and a first field plate electrode above the compound semiconductor layered structure,
wherein the first insulating film has the irregularities formed on the surface thereof by the gate electrode and the first field plate electrode.

10. The method of manufacturing a compound semiconductor device according to claim 8,
wherein the interlayer insulating film further comprises a third insulating film that is formed on the second insulating film and has a flat surface.

11. The method of manufacturing a compound semiconductor device according to claim 10, further comprising:
forming a second field plate electrode on the third insulating film.

12. The method of manufacturing a compound semiconductor device according to claim 10,
wherein the interlayer insulating film further comprises:
a fourth insulating film formed on the third insulating film; and
a fifth insulating film that is formed on the fourth insulating film to fill irregularities on a surface of the fourth insulating film and has a flat surface.

13. The method of manufacturing a compound semiconductor device according to claim 12, further comprising:
forming a sixth insulating film that has a flat surface, on the fifth insulating film.

14. The method of manufacturing a compound semiconductor device according to claim 13, further comprising:
forming a wiring layer on the sixth insulating film.

15. A power supply circuit comprising a transformer, and a high-voltage circuit and a low-voltage circuit across the transformer,
the high-voltage circuit comprising a transistor,
the transistor comprising:
a compound semiconductor layered structure; and
an interlayer insulating film that covers a surface of the compound semiconductor layered structure,
the interlayer insulating film comprising:
a first insulating film; and
a second insulating film that is formed on the first insulating film to fill irregularities on a surface of the first insulating film and has a flat surface.
